(19) United States
(12) Patent Application Publication
(10) Pub. No.: US 2008/0111244 A1
(43) Pub. Date: May 15, 2008

(54) COPPER-METALLIZED INTEGRATED CIRCUITS HAVING AN OVERCOAT FOR PROTECTING BONDABLE METAL CONTACTS AND IMPROVING MOLD COMPOUND ADHESION

(75) Inventors: Glenn J. Tessmer, Richardson, TX (US); Edgardo R. Hortaleza, Garland, TX (US); Thad E. Briggs, Dallas, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/559,966

(22) Filed: Nov. 15, 2006

(51) Int. Cl. H01L 21/56; H01L 23/50

(52) U.S. Cl. 257/765; 438/598

(57) ABSTRACT

A semiconductor device having copper interconnecting metallization (111) protected by a first (102) and a second (120) overcoat layer (homogeneous silicon dioxide), portions of the metallization exposed in a window (103) opened through the thicknesses of the first and second overcoat layers. A patterned conductive barrier layer (130) is positioned on the exposed portion of the copper metallization and on portions of the second overcoat layer surrounding the window. A bondable metal layer (150) is positioned on the barrier layer; the thickness of this bondable layer is suitable for wire bonding. A third overcoat layer (160) consist of a homogeneous silicon nitride compound is positioned on the second overcoat layer so that the ledge (162, more than 500 nm high) of the third overcoat layer overlays the edge (150b) of the bondable metal layer. The resulting contoured chip surface improves the adhesion to plastic device encapsulation.

### FIELD OF THE INVENTION

The present invention is related in general to the field of electronic systems and semiconductor devices and more specifically to bond pad structures and fabrication methods of copper metallized integrated circuits.

### DESCRIPTION OF THE RELATED ART

In integrated circuits (IC) technology, pure or doped aluminum has been the metallization of choice for interconnection and bond pads for more than four decades. Main advantages of aluminum include ease of deposition and patterning. Further, the technology of bonding wires made of gold, copper, or aluminum to the aluminum bond pads has been developed to a high level of automation, miniaturization, and reliability.

In the continuing trend to miniaturize the ICs, the RC time constant of the interconnection between active circuit elements increasingly dominates the achievable IC speed-power product. Consequently, the relatively high resistivity of the interconnecting aluminum now appears inferior to the lower resistivity of metals such as copper.

Further, the pronounced sensitivity of aluminum to electromigration is becoming a serious obstacle. Consequently, there is now a strong drive in the semiconductor industry to employ copper as the preferred interconnecting metal, based on its higher electrical conductivity and lower electromigration sensitivity. From the standpoint of the mature aluminum interconnection technology, however, this shift to copper is a significant technological challenge.

Copper has to be shielded from diffusing into the silicon base material of the ICs in order to protect the circuits from the carrier lifetime killing characteristic of copper atoms positioned in the silicon lattice. For bond pads made of copper, the formation of thin copper(I)oxide films during the manufacturing process flow has to be prevented, since these films severely inhibit reliable attachment of bonding wires, especially for conventional gold-wire ball bonding. In contrast to aluminum oxide films overlying metallic aluminum, copper oxide films overlying metallic copper cannot easily be broken by a combination of thermocompression and ultrasonic energy applied in the bonding process. As further difficulty, bare copper bond pads are susceptible to corrosion.

In order to overcome these problems, the semiconductor industry adopted a structure to cap the clean copper bond pad with a layer of aluminum and thus re-construct the traditional situation of an aluminum pad to be bonded by conventional gold-wire ball bonding. The described approach, however, has several shortcomings. First, the fabrication cost of the aluminum cap is higher than desired, since the process requires additional steps for depositing metal, patterning, etching, and cleaning. Second, the cap must be thick enough to allow reliable wire bonding and to prevent copper from diffusing through the cap metal and possibly poisoning the IC transistors.

Third, the aluminum used for the cap is soft and thus gets severely damaged by the markings of the multiprobe contacts in electrical testing. This damage, in turn, becomes so dominant in the ever decreasing size of the bond pads that the subsequent ball bond attachment is no longer reliable. Finally, the elevated height of the aluminum layer over the surrounding overcoat plane enhances the risk of metal scratches and smears. At the tight bond pad pitch of many high input/output circuits, any aluminum smear represents an unacceptable risk of shorts between neighbor pads.

### SUMMARY OF THE INVENTION

Applicants have recognized the need for a metallurgical bond pad structure suitable for ICs with copper interconnection metallization, which combines a low-cost method of fabricating the bond pad structure, a perfect control of up-diffusion, a risk elimination of smearing or scratching, and a reliable method of bonding wires to these pads.

Applicants have further recognized the opportunity to use the novel bond pad structure for substantially eliminating puzzling reliability failures recently observed in copper-metallized integrated circuits: The high number of patterning steps needed for producing circuits with multi-level metallization has introduced the methodology of planarizing the wafers, for instance by processes such as chemical-mechanical polishing. When finished devices with planarized chip surfaces are encapsulated in plastic materials such as molding compounds and then subjected to accelerated stress tests, recent failure data have shown that devices with planarized chip surfaces exhibit a substantially increased risk for plastic delamination and thus reduced device reliability.

The novel bond pad structure should be flexible enough to be applied for different IC product families and a wide spectrum of design and process variations. Preferably, these innovations should be accomplished while shortening production cycle time and increasing throughput, and improved manufacturability.

One embodiment of the invention is an integrated circuit, which has copper interconnecting metallization covered by a first insulting overcoat layer (preferably silicon nitride of 30 to 50 nm thickness). On the first overcoat layer is a second insulating overcoat layer, which consists of homogeneous silicon dioxide in the 200 to 1200 nm thickness range. A portion of the copper metallization is exposed in a window opened through the first and second overcoat layers. A patterned conductive barrier layer is positioned on the exposed portion of the copper metallization, on the window rim, and on a portion of the second overcoat layer adjacent to the window rim. A metal layer suitable for wire bonding covers the patterned barrier layer. A third insulating overcoat layer, which consists of a homogeneous silicon nitride compound, is on the second overcoat layer; it forms a ledge of more than 500 nm height over the bondable metal layer.

Another embodiment of the invention is a wafer-level method of fabricating a metal structure for a contact pad of an integrated circuit, which has copper interconnecting metallization. The wafer surface is planarized to expose at least portions of the copper metallization. For protecting the exposed copper, a first insulating overcoat layer (preferably of 30 to 50 nm silicon nitride) is deposited over the planar wafer surface. A second insulating overcoat layer of homogeneous silicon dioxide (preferably 200 to 1200 nm thick) is deposited on the first overcoat layer. A window is then opened through the first and second overcoat layers to expose portions of the copper metallization. Next, a conductive barrier metal layer (preferably of 20 to 30 nm tantalum nitride) is deposited on the exposed copper metallization, the window rim, and the second overcoat layer.

A layer of bondable metal (aluminum or aluminum alloy, 400 to 1400 nm thick for wire ball bonding) is deposited on the on the barrier layer. The bondable and the barrier layers are then patterned to retain only the portions inside the window, over the rim, and portions of the second overcoat adjacent to the window rim. A third insulating overcoat layer, which consists of a homogeneous silicon nitride compound of more than 500 nm thickness, is deposited on the second overcoat layer and the bondable metal layer. Finally, the third overcoat layer is selectively removed from the bondable metal layer so that the metal edge remains covered by the overcoat and an overcoat ledge of more than 500 nm height is formed over the edge of the bondable metal. As a result, the bondable metal edge is protected and the wafer surface is contoured by steps of more that 500 nm, offering improved mechanical grips for the plastic molding compound.

Embodiments of the present invention are related to wire-bonded IC assemblies, semiconductor device packages, surface mount and chip-scale packages. It is a technical advantage that the invention offers a low-cost method of reducing the risk of aluminum-smearing or—scratching and electrical shorting between contact pads. The assembly yield of high input/output devices can thus be significantly improved. It is an additional technical advantage that the invention facilitates the shrinking of the pitch of chip contact pads without the risk of yield loss due to electrical shorting. Further technical advantages include the opportunity to scale the assembly to smaller dimensions, supporting the ongoing trend of IC miniaturization.

The technical advantages represented by certain embodiments of the invention will become apparent from the following description of the preferred embodiments of the invention, when considered in conjunction with the accompanying drawings and the novel features set forth in the appended claims.

### BRIEF DESCRIPTION OF THE DRAWINGS

FIG. 1 is a schematic cross section of an embodiment of the invention depicting a contact pad of a semiconductor device with copper metallization, wherein the contact pad has a bondable metal plug closely surrounded by a (third) protective overcoat.

FIG. 2 is a schematic cross section of the bond pad metallization according to the invention, with a ball bond attached to the bondable metal plug.

FIG. 3 is a block diagram of the device fabrication process flow according to another embodiment of the invention.

### DETAILED DESCRIPTION OF THE PREFERRED EMBODIMENTS

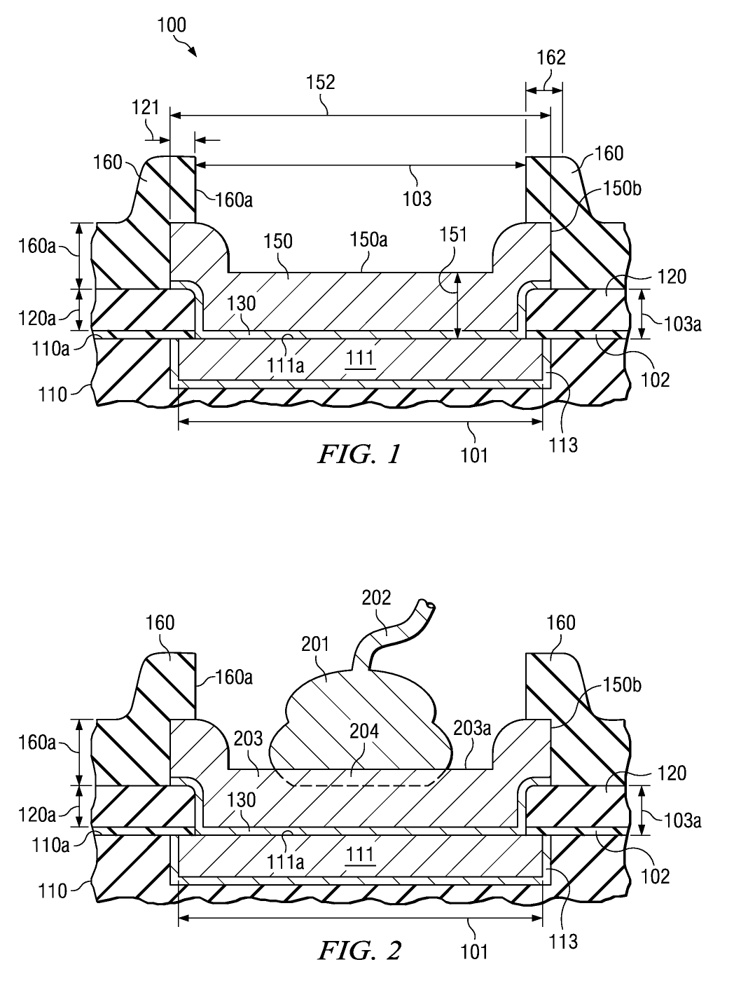

FIG. 1 illustrates an embodiment of the invention, generally designated 100, in a portion of a semiconductor wafer with the contact pad of a device such as an integrated circuit (IC). The wafer portion shown in FIG. 1 includes an insulating material 110, which may consist of silicon dioxide, or a low-k dielectric material, or a stack of dielectric materials. Embedded in the insulating material is a patterned portion 111 of the device interconnecting metallization made of copper or a copper alloy. Illustrated is specifically the portion 111 of the copper layer intended to provide a contact pad. The thickness of the copper layer is preferably in the range from 200 to 500 nm. The copper metallization is contained by conductive barrier layer 113 from diffusing into insulator 110; barrier layer 113 is preferably made of tantalum nitride and about 10 to 30 nm thick. The width of the bond pad copper layer is designated 101 and is typically in the range from 30 to 60 μm.

As FIG. 1 indicates, the exposed surface (top surface) 111a of copper layer 111 is at the same level as the top surface 110a of the dielectric material 110. The reason for this uniformity is the method of fabrication involving a chemical-mechanical polishing step (see below).

On copper metallization 111 is a first insulating overcoat layer 102; it preferably about 30 to 50 nm thick and consists of silicon nitride as a practically moisture-impermeable or moisture-retaining material; it also is mechanically hard. On the first overcoat layer 102 is a second insulating overcoat layer 120, which consists of homogeneous silicon dioxide. The thickness 120a of layer 120 is preferably in the range from about 200 to 1200 nm; it is more preferably about 1000 nm.

A window of width 103 through the second and the first overcoat layers exposes the portion of width 102 of the copper metallization 111. The height 103a of the window rim is for all practical purposes determined by the dioxide layer thickness 120a and can consequently be kept relatively low.

In order to establish low-resistance ohmic contact to copper layer 111, one or more conductive barrier layers 130 are deposited over the copper, as indicated in FIG. 1. For a single layer, tantalum nitride is the preferred selection. For a couple of layers, the first barrier layer is preferably selected from titanium, tantalum, tungsten, molybdenum, chromium and alloys thereof; the layer is deposited over the exposed copper 111 with the intent to establish good ohmic contact to the copper by “gettering” any oxide away from the copper. A second barrier layer, commonly nickel vanadium, is deposited to prevent outdiffusion of copper. The barrier layer has a thickness preferably in the range from 20 to 30 nm. Barrier layer 130 may be patterned using the same photomask employed for defining the width 101 of the copper layer 111.

Covering the patterned barrier layer 130 is a layer 150 of bondable metal, which has a thickness suitable for wire ball bonding. The preferred thickness ranges from about 400 to 1400 nm. Because of this considerable thickness, layer 150 is often referred to as a plug. The bondable metal is preferably aluminum or an aluminum alloy, such as aluminum-copper alloy. In FIG. 1, the exposed surface of this plug is designated 150a. As FIG. 1 shows, the bondable metal layer has an edge 150b, which is created by the step of patterning layer 150, preferably using the same photomask as for patterning barrier layer 130. The diameter of the complete area covered by the bondable plug is designated 152.

Since the surfaces 110a and 111a are on a common level, the combined thicknesses of barrier layer 130 and bondable plug 150 stick out geometrically above this common level; in FIG. 1, this combined height above the level is designated 151. Furthermore, after patterning the barrier layer 130 and bondable layer 150, both layers typically overlap the edges of the window over the second protective overcoat 120 by a distance 121 around the perimeter of window 103. Typically, distance 121 is between about 100 and 300 nm. Elevated by the combined thickness 103a of the first and the second overcoat, the full height 151 thus becomes exposed on the surface of second overcoat 120.

In order to protect the exposed thickness 151 of layers 150 and 130, a third insulating overcoat layer 160 is positioned on the second overcoat layer 120 and the edge 150b of the bondable metal layer 150. The third overcoat layer 160 consists of a homogeneous silicon nitride compound such as silicon oxynitride. Silicon nitride compounds are practically moisture impermeable or moisture retaining, and mechanically hard. Layer 160 has a thickness 160a of more than 500 nm, preferably about 1000 nm. It is patterned preferably by the same photomask used to pattern the second and first overcoat layers. The opened window has thus the same diameter 103 and forms a ledge 160a of more than 500 nm height; in devices with a 1000 nm thick layer 160, ledge 160a is also about 1000 nm high. The ledge of overcoat 160 has a contoured outline to form an overlap over the edge of the bondable metal layer for a length of about 100 to 300 nm. In FIG. 1, the contoured overlay is designated 162.

The protection by the third overcoat ledge of the bondable metal edge represents a substantial reduction of accidental scratching or smearing of the bondable metal. There are numerous wafer and chip handling steps in a typical assembly process flow after the patterning of the bondable metal: The most important steps include back-grinding; transporting the wafer from the fab to the assembly facility; placing the wafer on a tape for sawing; sawing and rinsing the wafer; attaching each chip onto a leadframe; wire bonding; and encapsulating the bonded chip in molding compound. At each one of these process steps, and between the process steps, accidental scratching or smearing could happen, but can be substantially reduced by the protection afforded by the third overcoat layer according to the invention.

As an example of the bond pad capability improved by the protection of the third overcoat, FIG. 2 illustrates the contact pad of FIG. 1 after the chip has been singulated from the wafer in a sawing process, assembled on a supportive substrate or leadframe, and a ball bond has been attached. A free air ball 201 (preferably gold) of a metal wire 202 (preferably gold) is pressure-bonded (squeezed) to the undisturbed surface 203a of the plug 203 (preferably aluminum or an aluminum alloy). In the bonding process, gold-aluminum intermetallic compounds 204 are formed in the contact region of ball and plug; the intermetallic compounds may actually consume most of the aluminum under the gold ball.

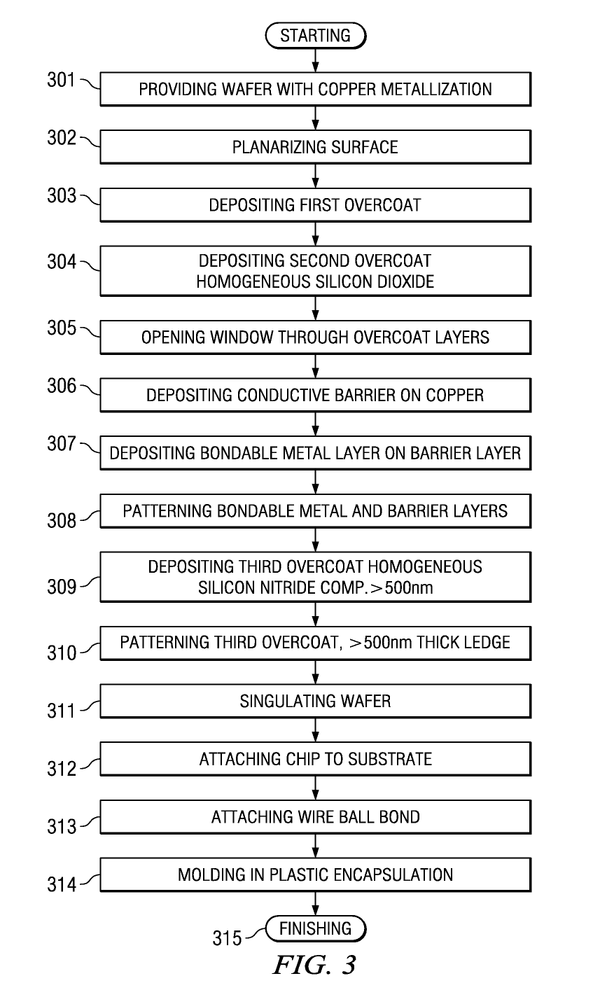

Another embodiment of the invention is a wafer-level method of fabricating a metal structure for a contact pad on the semiconductor wafer. The process flow is displayed in the schematic block diagram of FIG. 3. In step 301 of the method, a semiconductor wafer with an interconnecting copper metallization is provided. In step 302, the wafer surface is planarized, for example by chemical-mechanical polishing, to expose at least portions of the copper metallization. Right after the exposure of the copper, a first insulating overcoat layer (a thickness of 30 to 50 nm is sufficient) is deposited over the planar wafer surface in order to protect the copper against ambient influences such as oxidation (step 303). A preferred material for the first overcoat is silicon nitride, which is practically moisture impermeable and mechanically hard.

In step 304, a second insulating overcoat is deposited on the first overcoat layer. The second overcoat layer consists of homogeneous silicon dioxide in the thickness range from about 200 to 1200 nm; a preferred thickness is about 1000 nm. The preferred deposition technique is chemical vapor deposition. The next step 305 opens a window through the first and second overcoat layers in order to expose portions of the copper metallization. The copper is intended to become the metal of the bond pad and has a certain width. The window has a rim with walls reaching through the thickness of the first and second overcoat layers. The width of the window is somewhat smaller than the width of the copper metallization of the bond pad.

In the next process step 306, a thin barrier metal layer in the thickness range from about 20 30 nm is deposited over the wafer. Preferred barrier metal choices include tantalum or tantalum nitride, and nickel vanadium. Inside the window, this conductive barrier metal layer covers the exposed copper metallization and the window rim walls; outside the window, the barrier layer covers the second overcoat surface. In step 307, a bondable metal layer is deposited over the barrier layer in a thickness sufficient to fill the overcoat window and to enable wire ball bonding. Preferred bondable metal choices include aluminum and aluminum alloy, and the preferred thickness range is from about 400 10 1400 nm, with a more preferred thickness of about 1000 nm.

In the next process step 308, both the barrier metal layer and the bondable metal layer are patterned so that only those layer portions are retained, which are inside the window, over the rim walls, and over portions of the second overcoat adjacent to the window rim. It is a preferred option to use for this etching step the same photomask, which had been used to define the width of the copper bond pad metallization. Obviously, this etching process leaves the bondable metal layer with an edge.

In step 309, a third insulating overcoat layer is deposited on the second overcoat layer and the bondable metal layer for mechanical and moisture protection. The third overcoat consists of a homogeneous silicon nitride compound such as silicon oxynitride and has a thickness of more than 500 nm. The preferred thickness is about 1000 nm. The preferred deposition process is a chemical vapor deposition method.

In step 310, the third overcoat layer is patterned by selectively removing overcoat material over the bondable metal layer so that the metal edge remains covered by the overcoat. Preferably, the patterning is performed using the photoresist, photomask, and illumination techniques in the same fashion as for the patterning step of the first and second overcoat layers. It is preferred to leave un-removed an overcoat ledge of about 100 to 300 nm length and, of course, more than 500 nm height over the edge of the bondable metal layer. Since the amount of the overlay over the edge of the bondable metal is determined by the photomask used, it can be expanded in a predetermined manner. When the same photomask for the patterning of the first and the second overcoat is employed, the repeated usage represents a process simplification and low cost feature.

In step 311, the wafer is singulated into discrete chips; a preferred method is sawing. In step 312, a selected chip is attached to a substrate or leadframe. In step 313, a wire ball bond (preferably gold) is attached to the bondable metal layer of a chip bond pads. In step 314, the chip surface including the bonded metal contact structure is molded in plastic encapsulation compound. The compound, preferably an epoxy-based thermoset compound filled with inorganic particles, is polymerized. In accelerated stress tests of the molded device, the superior adhesion of the molding compound to the contoured chip surface results in much improved device reliability data and reduced delamination failure rates.

The method concludes at step 315.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, for certain products the deposition method for the silicon dioxide layer and/or the silicon oxynitride layer may be a sputtering technique rather than chemical vapor deposition. It is therefore intended that the appended claims encompass any such modifications and embodiments.

We claim:

1. An integrated circuit comprising:
an interconnecting copper metallization;
a first insulating overcoat layer on the metallization;
a second insulating overcoat layer on the first overcoat layer, the second overcoat layer consisting of homogeneous silicon dioxide;
portions of the copper metallization exposed in a window through the first and second overcoat layers, the window having a rim;
a patterned conductive barrier layer on the exposed copper metallization, the window rim, and a portion of the second overcoat layer adjacent to the window rim;
a layer of bondable metal covering the patterned barrier layer, the bondable metal layer having an edge; and
a third insulating overcoat layer on the second overcoat layer and the edge of the bondable metal layer, the third insulating layer consisting of a homogeneous silicon nitride compound and forming a ledge of more than 500 nm height over the bondable metal layer.

2. The circuit according to claim 1 wherein the first insulating overcoat layer is made of silicon nitride and has a thickness between about 30 to 50 nm.

3. The circuit according to claim 1 wherein the second overcoat has a thickness in the range from about 200 to 1200 nm.

4. The circuit according to claim 1 wherein said barrier layer includes tantalum nitride and has a thickness in the range from about 20 to 30 nm.

5. The circuit according to claim 1 wherein the bondable metal layer includes aluminum or aluminum alloy and has a thickness in the range from about 400 to 1400 nm.

6. The circuit according to claim 1 further including a ball bond attached to the bondable metal layer.

7. The circuit according to claim 1 wherein the barrier and bondable metal layers overlap over the surrounding second overcoat layer for a length of about 100 to 300 nm.

8. The circuit according to claim 1 wherein the ledge of the third overcoat layer overlaps over the edge of the bondable metal layer for a length of about 100 to 300 nm.

9. A method for fabricating a metal contact structure on a semiconductor wafer comprising the steps of:
providing a semiconductor wafer having an interconnecting copper metallization;
planarizing the wafer surface to expose at least portions of the copper metallization;
depositing a first insulating overcoat layer over the planar wafer surface;
depositing a second insulating overcoat layer on the first overcoat layer, the second overcoat layer consisting of homogeneous silicon dioxide;
opening a window through the first and second overcoat layers to expose portions of the copper metallization, the window having a rim;
depositing a conductive barrier metal layer on the exposed copper metallization, the window rim, and the second overcoat layer;
depositing on the barrier layer a layer of bondable metal in a thickness suitable for wire ball bonding;
patterning the bondable and the barrier layers to retain only the portions inside the window, over the rim, and portions of the second overcoat adjacent to the window rim, whereby the bondable metal layer obtains an edge;
depositing a third insulating overcoat layer on the second overcoat layer and the bondable metal layer, the third overcoat layer consisting of a homogeneous silicon nitride compound and having a thickness of more than 500 nm; and
selectively removing the third overcoat layer from the bondable metal layer so that the metal edge remains covered by the overcoat and an overcoat ledge of more than 500 nm height is formed over the edge of the bondable metal.

10. The method according to claim 9 wherein the first layer of insulating overcoat is made of silicon nitride and has a thickness in the range from about 30 to 50 nm.

11. The method according to claim 9 wherein the silicon dioxide layer has a thickness between about 200 and 1200 nm.

12. The method according to claim 9 wherein the barrier metal layer includes tantalum nitride in the thickness range from about 20 to 30 nm.

13. The method according to claim 9 wherein the bondable metal layer includes aluminum or aluminum alloy in the thickness range from about 400 to 1400 nm.

14. The method according to claim 9 further including, after selectively removing the third overcoat layer, the steps of singulating the wafer into discrete chips, attaching a selected chip onto a leadframe, and attaching a wire ball bond to the bondable metal layer of the chip.

15. The method according to claim 14 further including, after the step of attaching a ball bond, the step of molding the chip surface including the bonded metal contact structure in plastic encapsulation compound.
